(19) United States
(12) Patent Application Publication
(10) Pub. No.: US 2024/0140875 A1
(43) Pub. Date: May 2, 2024

(54) SINTERED BODY AND PARTS INCLUDING SAME

(71) Applicant: SK enpulse Co., Ltd., Pyeongtaek-si (KR)

(72) Inventors: Kyung yeol MIN, Seoul (KR); Yongsoo CHOI, Seoul (KR); SungSic HWANG, Seoul (KR); Kyung In KIM, Seoul (KR); Jung Kun KANG, Seoul (KR); Su Man CHAE, Seoul (KR)

(73) Assignee: SK enpulse Co., Ltd., Pyeongtaek-si (KR)

(21) Appl. No.: 18/468,903

(22) Filed: Sep. 18, 2023

(30) Foreign Application Priority Data
Oct. 27, 2022 (KR) 10-2022-0140204

(51) Int. Cl. C04B 35/563; C04B 35/626; C04B 35/634; C04B 35/64; H01J 37/32

(52) U.S. Cl. CPC C04B 35/563; C04B 35/6261; C04B 35/6264; C04B 35/62655; C04B 35/62695; C04B 35/63424; C04B 35/63476; C04B 35/64; H01J 37/32642; C04B 2235/3821; C04B 2235/422; C04B 2235/606; C04B 2235/6562; C04B 2235/6565; C04B 2235/6567; C04B 2235/661; C04B 2235/723; C04B 2235/728; C04B 2235/782; C04B 2235/786; C04B 2235/9607; C04B 2235/9669; H01J 2237/334

(57) ABSTRACT

The sintered body including boron carbide, wherein the sintered body includes a zone, in which a volume ratio of grains having a grain size of greater than 30 μm and 60 μm or less is in a range of 50% to 70% based on a total volume of grains, as observed on a surface of the sintered body, is disclosed.

### CROSS-REFERENCE TO RELATED APPLICATION

This application claims the benefit under 35 USC § 119(a) of Korean Patent Application No. 10-2022-0140204, filed on Oct. 27, 2022, the disclosure of which is incorporated herein by reference in its entirety.

### BACKGROUND

### 1. Field

The present disclosure relates to a sintered body having improved plasma etching resistance and a part of a plasma processing apparatus including the same.

### 2. Discussion of Related Art

A plasma processing apparatus has an upper electrode and a lower electrode disposed inside a chamber, and includes a semiconductor wafer, a glass substrate, and the like placed on the lower electrode, and thus operates by applying an electric power between the upper and lower electrodes. Electrons accelerated by an electric field between the upper and lower electrodes, electrons emitted from the electrodes, or heated electrons ionically collide with molecules of a processing gas, which results in production of plasma from the processing gas. Reactive species such as radicals or ions in such plasma are allowed to perform desired micro processing, for example, etching processing, on a surface of an etching target.

A design for manufacture of microelectronic components is becoming increasingly elaborate. In particular, plasma etching requires higher dimensional accuracy, and uses significantly higher power. Such a plasma processing apparatus includes a focus ring installed therein, which is affected by plasma.

When a plasma power increases, a wavelength effect, in which standing waves are formed, and a skin effect, by which an electric field is concentrated at the center of a surface of the electrode, and the like, may be formed. As a result, the plasma distribution is mostly maximized in a central portion of an etching target and becomes the lowest in an edge portion of the target, which may result in increased non-uniformity of the plasma distribution on the substrate and degraded quality of the microelectronic components.

A focus ring located outside the etching target and configured to hold the etching target may reduce the effect of an electric field distribution outside the etching target and somewhat relieve the non-uniformity of the plasma distribution. However, an etching rate of the focus ring is highly relative to the plasma treatment time, and the plasma distribution may also be affected depending on the etching. Accordingly, there is a need for improvement measures capable of enhancing the etching resistance and replacement period of such a focus ring, thereby achieving processing efficiency.

The above-described background is technical information that the inventor possessed or acquired for conceiving embodiments of the present disclosure, and cannot necessarily be a known technology disclosed to a general public prior to the filing of the present disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, the sintered body includes boron carbide, wherein the sintered body includes a zone, in which a volume ratio of grains having a grain size of greater than 30 μm and 60 μm or less may be in a range of 50% to 70% based on a total volume of grains, as observed on a surface of the sintered body.

A volume ratio of the grains having a grain size of 10 μpm or less may be in a range of 0.01% to 1% based on the total volume of grains.

A volume ratio of the grains having a grain size of greater than 60 μm and 80 μm or less may be in a range of 12% to 20% based on the total volume of grains.

The sintered body may have an average grain size of 30 μm to 70 μm.

The sintered body may have a boron and carbon content of 97% by weight or more based on a total weight of the sintered body.

The sintered body may have an etching rate of 1.8% or less, as measured according to the following Equation 1 under plasma etching conditions, where a chamber pressure is 100 mTorr, a plasma power is 800 W, an exposure time is 300 minutes, a CF₄ gas flow rate is 50 sccm, an Ar gas flow rate is 100 sccm, and an O₂ gas flow rate is 20 sccm in the chamber:

Etching Rate={(Thickness before etching−Thickness after etching)/(Thickness after etching)}×100% [Equation 1]

The sintered body may have a thermal conductivity at 25° C. of 23 W/mK or more and 42 W/mK or less.

In another general aspect, the sintered body includes boron carbide, wherein the sintered body may have a carbon content of 30% by weight to 43% by weight based on the total weight of the sintered body, as measured by X-ray fluorescence spectrometry.

The sintered body may have an oxygen content of 0.1% by weight to 0.9% by weight based on the total weight of the sintered body, as measured by X-ray fluorescence spectrometry.

The sintered body may have a silicon content of 0.05% by weight to 0.5% by weight based on the total weight of the sintered body, as measured by X-ray fluorescence spectrometry.

The sintered body may have a boron and carbon content of 97% by weight

or more.

The sintered body may have an etching rate of 1.8% or less, as measured according to the following Equation 1 under plasma etching conditions, where a chamber pressure is 100 mTorr, a plasma power is 800 W, an exposure time is 300 minutes, a CF₄ gas flow rate is 50 sccm, an Ar gas flow rate is 100 sccm, and an O₂ gas flow rate is 20 sccm in the chamber:

Etching Rate={(Thickness before etching−Thickness after etching)/(Thickness after etching)}×100% [Equation 1]

The sintered body may have a thermal conductivity at 25° C. of 23 W/mK or more and 42 W/mK or less.

In another general aspect, the method of manufacturing a sintered body includes: thermally treating a molded body, which is manufactured by molding a raw material composition, at a temperature of 500° C. to 1,000° C., to prepare a carbonized molded body; thermally treating the carbonized molded body at a temperature of 2,100° C. to 2,300° C. to prepare a first sintered molded body; and thermally treating the first sintered molded body at a temperature of 2,200° C. to 2,320° C. to prepare a second sintered molded body, wherein the raw material composition includes boron carbide, a carbon-based material, and a sinterability enhancer.

The raw material composition may include raw material granules obtained by spray drying a raw material slurry comprising boron carbide, a carbon-based material, a sinterability enhancer, and a solvent.

The first sintered molded body and the second sintered molded body may be prepared by sintering at a pressure of 0.2 MPa or less.

The first sintered molded body may be prepared by sintering for 0.5 hours to 2 hours.

The second sintered molded body may be prepared by sintering for 1 hour to 3 hours.

In another general aspect, the part included in a plasma processing apparatus, may include the sintered body.

Other features and aspects will be apparent from the following detailed description, the drawings, and the claims.

### BRIEF DESCRIPTION OF THE DRAWINGS

The above and other objects, features and advantages of the present disclosure will become more apparent to those of ordinary skill in the art by describing in detail embodiments thereof with reference to the accompanying drawings.

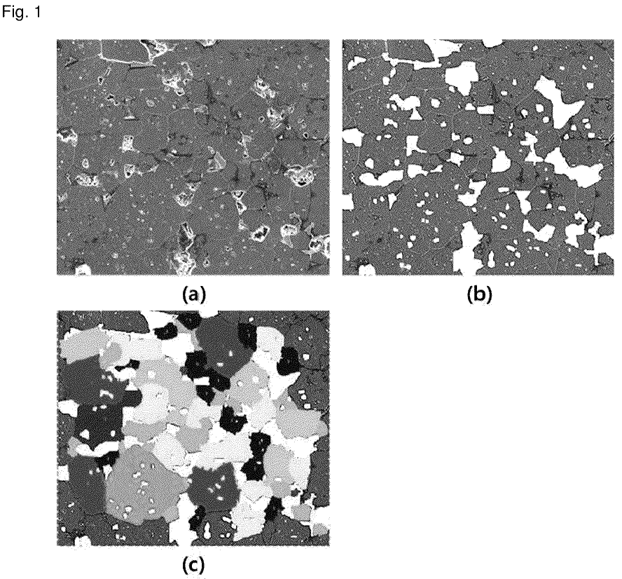

(a) of FIG. 1 is a scanning electron micrograph showing the surface of the sintered body of Example 1 before electrolytic etching in the Experimental Example, (b) of FIG. 1 is a scanning electron micrograph showing the surface of the sintered body of Example 1 after electrolytic etching in the Experimental Example, and (c) of FIG. 1 shows the identifiable grains on the scanning electron micrograph of the surface of the sintered body of Example 1 after electrolytic etching in the Experimental Example by color.

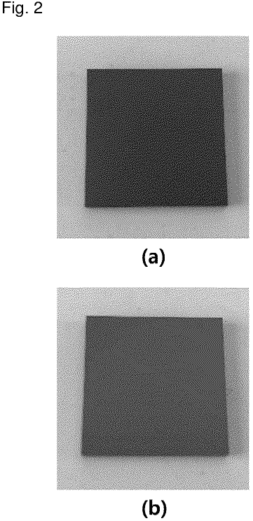

(a) of FIG. 2 is an image showing the state of the sample of Example 1 after plasma etching in the Experimental Example, and (b) of FIG. 2 is an image showing the state of the sample of Comparative Example 1 after plasma etching in the Experimental Example.

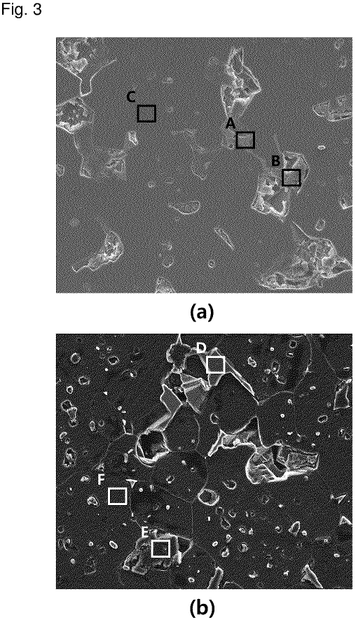

(a) of FIG. 3 is a diagram showing the surface of the sintered body of Example 1 and positions for composition measurement before electrolytic etching, and (b) of FIG. 3 is a diagram showing the surface of the sintered body of Example 1 and positions for composition measurement after electrolytic etching.

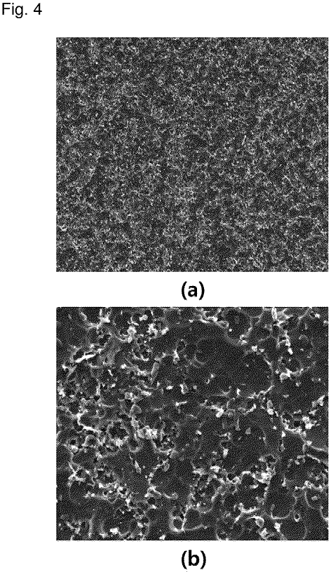

(a) of FIG. 4 is a diagram showing the surface state of the sintered body of Example 1 before plasma etching, and (b) of FIG. 4 is a diagram showing the surface state of the sintered body of Example 1 after plasma etching.

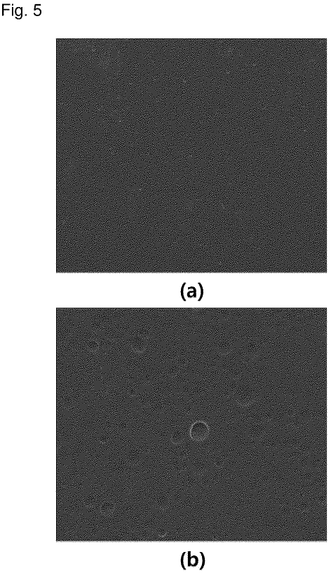

(a) of FIG. 5 is a diagram showing the surface state of the sintered body of Comparative Example 1 before plasma etching, and (b) of FIG. 5 is a diagram showing the surface state of the sintered body of Comparative Example 1 after plasma etching.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION OF EXEMPLARY EMBODIMENTS

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Throughout the specification, unless otherwise specified, when an element is referred to as “including” another element, it will be understood to mean the inclusion of stated elements but not the exclusion of any other elements.

Throughout the specification, when an element is referred to as being “connected” or “coupled” to another element, it can be directly connected or coupled to the other element or intervening elements may be present.

In the present specification, it will be understood that when “B” is referred to as being on “A,” “B” can be directly on “A” or other component(s) may be interposed therebetween. That is, the location of “B” is not construed as being limited to direct contact of “B” with the surface of “A.”

Throughout the specification, the term “combination of” included in Markush type description refers to a mixture or combination of one or more components selected from a group consisting of components described in the Markush form and thereby means including one or more components selected from the Markush group.

In the present specification, the description of “A and/or B” means “A, or B, or A and B.”

In the present specification, the terms such as “first,” “second” or “A,” “B” are used to distinguish the same terms from each other, unless otherwise specified.

In the present specification, the singular forms “a” “an” and “the” are intended to include the plural forms as well, unless the context clearly specifies otherwise.

It is an object of present disclosure to provide a sintered body having improved plasma etching resistance and capable of inducing a uniform plasma distribution on an etching target, and a part including the same.

### Sintered Body

To achieve the above objects, the sintered body according to the present disclosure includes boron carbide, wherein the sintered body may include a region, in which a volume ratio of grains having a grain size of greater than 30 μm and 60 μm or less is in a range of 50% to 70% based on the total volume of grains, as observed on a surface of the sintered body, and wherein the sintered body may have a carbon content of 30% to 43% by weight based on the total weight of the sintered body, as measured by X-ray fluorescence spectrometry.

The boron carbide of the sintered body may be substantially B₄C.

The sintered body is based on the boron carbide, includes certain carbon distinct from the boron carbide, and may further include some silicon, silicon carbide (SixCy) oxygen, boron oxide, and the like. The carbon, silicon carbide, and the like of the sintered body may be included in the form of a secondary phase.

The sintered body may include boron carbide grains, and the boron carbide grains may also be observed on the surface of the sintered body.

The sintered body may have an average grain size that is coarser than that of a conventional boron carbide sintered body.

In the sintered body, the volume ratio of grains having a grain size of greater than 30 μm and 60 μm or less may be in a range of 50% to 70%, and in a range of 55% to 65%, based on the total volume of grains.

In the sintered body, the volume ratio of grains having a grain size of 10 μm or less may be in a range of 0.01% to 1%, and in a range of 0.01% to 0.81%, based on the total volume of grains.

In the sintered body, the volume ratio of grains having a grain size of 20 μm or less may be in a range of 2% to 14%, and in a range of 1% to 10%, based on the total volume of grains.

In the sintered body, the volume ratio of grains having a grain size of greater than 60 μpm and 80 μm or less may be in a range of 12% to 20%, and in a range of 14% to 18%, based on the total volume of grains.

In the sintered body, the volume ratio of grains having a grain size of greater than 40 μm may be in a range of 44% to 65%, and in a range of 49% to 60%, based on the total volume of grains.

In the sintered body, the volume ratio of grains having a grain size of greater than 70 μm may be in a range of 8% to 15%, and in a range of 9.1% to 13.7%, based on the total volume of grains.

The sintered body may have an average grain size of 30 μm to 70 μm, or an average grain size of 45 μm to 65 μm.

The grain size analysis of the sintered body may be performed using a method described in the following experimental example, and may be based on the grain size observed on the surface of the sintered body.

The sintered body having these grain characteristics may reduce the generation of impurity particles during plasma etching due to decreased line defects, may have excellent plasma etching resistance, and may help maintain plasma etching resistance.

The sintered body may have a purity of 97% or more, 99% or more, and 99.2% or more, based on the boron and carbon (B, C).

The purity may be evaluated based on weight by X-ray fluorescence spectrometry (XRF).

The sintered body may have a carbon content of 30% to 43% by weight, and 32% to 40% by weight, based on the total weight of the sintered body, as measured by X-ray fluorescence spectrometry. Such a carbon content may represent a content, in which carbon is further added to the stoichiometric carbon content (21.72% by weight) of boron carbide (B₄C). Also, the carbon content may be changed through the bonding relationship of boron carbide in a sintering process during the manufacture of the sintered body, or may also be obtained from the results produced by an effect of the carbon-based material added to the raw material during the manufacture of the sintered body.

The sintered body may have a boron content of 55% to 68% by weight, and 56% by weight to 66% by weight, based on the total weight of the sintered body, as measured by X-ray fluorescence spectrometry. Such a boron content may represent a content, in which boron is further added as described above, and may also be obtained from the results produced by the carbon-based material added to the raw material during the manufacture of the sintered body.

The sintered body may have an oxygen content of 0.1% to 0.9% by weight, and 0.3% to 0.7% by weight, based on the total weight of the sintered body, as measured by X-ray fluorescence spectrometry.

The sintered body may have a silicon content of 0.05% to 0.5% by weight, and 0.1% to 0.4% by weight, based on the total weight of the sintered body, as measured by X-ray fluorescence spectrometry.

As the sintered body has such contents of other elements, the sintered body may play a positive role in densification.

The sintered body may include 400 ppm or less, or 200 ppm or less, of metallic impurities. The metallic impurities may include sodium, aluminum, calcium, iron, nickel, and the like.

The sintered body may have a flexural strength of 365 MPa to 547 MPa, or a flexural strength of 410 MPa to 502 MPa.

The sintered body may have a Vicker's hardness of 26.1 GPa to 39.1 GPa, or a Vicker's hardness of 29.3 GPa to 35.9 GPa.

The sintered body may have a compressive strength of 549 MPa to 823 MPa, or a compressive strength of 617 MPa to 755 MPa.

The sintered body may have a modulus of elasticity of 308 GPa to 424 GPa, or a modulus of elasticity of 347 GPa to 424 GPa.

The sintered body may have a Poisson's ratio of 0.175 to 0.263, or a Poisson's ratio of 0.197 to 0.241.

The sintered body may have a thermal conductivity at 25° C. of 23 W/mK or more and 42 W/mK or less, or a thermal conductivity at 25° C. of 30 W/mK to 40 W/mK.

The sintered body may have a thermal expansion coefficient at 25° C. to 400° C. of 3.34×10⁻⁶/K to 5.02×10⁻⁶/K, or a thermal expansion coefficient at 25° C. to 400° C. of 3.76×10⁻⁶/K to 4.60×10⁻⁶/K.

The sintered body may have a thermal expansion coefficient at 400° C. to 800° C. of 4.01×10⁻⁶/K to 6.02×10⁻⁶/K, or a thermal expansion coefficient at 400° C. to 800° C. of 4.52×10⁻⁶/K to 5.52×10⁻⁶/K.

The sintered body may have a specific resistance of 0.05 Ωcm to 2 0Ωcm, or a specific resistance of 0.1 0Ωcm to 1 0Ωcm.

The sintered body having these characteristics may exhibit good reliability and durability when the sintered body is applied to parts of a plasma processing apparatus, and may help maintain plasma etching resistance.

The sintered body may have an etching rate of 1.8% or less, as measured according to the following Equation 1 under the plasma etching conditions of a chamber pressure of 100 mTorr, a plasma power of 800 W, a plasma exposure time of 300 minutes, a CF₄ gas flow rate of 50 sccm, an Ar gas flow rate of 100 sccm, and an O₂ gas flow rate of 20 sccm in the chamber:

Etching Rate={(Thickness before etching−Thickness after etching)/(Thickness after etching)}×100% [Equation 1]

The etching rate of the sintered body may be less than or equal to 1.6%, or less than or equal to 1.55%.

Because the sintered body has such plasma etching resistance and also has coarse grain characteristics, particle generation may be inhibited as much as possible during a plasma processing process.

The sintered body may have an etching rate reduced by 20% or more, or an etching rate reduced by 30% or more, under the plasma etching conditions, compared to the etching rate of silicon carbide provided by chemical vapor deposition (CVD).

The sintered body may have a relative density of 95% or more, or a relative density of 97% or more. The relative density may be less than or equal to 99.9%. The sintered body may have excellent relative density while showing a relatively coarse grain size.

### Part

To achieve the above objects, a part according to the present disclosure includes the sintered body, wherein the part may be applied inside a plasma processing apparatus.

The part may include the sintered body on a portion of a surface thereof, to which plasma may be exposed, and also may include the sintered body on the entire surface thereof.

The part may include the sintered body on a surface thereof, and also may include other ceramic materials (silicon carbide, silicon, and the like) on the surface thereof.

The part may be a part that may affect a flow of plasma ions during a plasma etching process, and examples of the part may include a focus ring, and the like. The focus ring may be applied as a support configured to support an edge of a wafer when the wafer is disposed inside the plasma processing apparatus.

When the part includes the sintered body, the part may have good plasma etching resistance, the replacement frequency of parts may be reduced, and the generation of particles that may have a negative effect on yield may be effectively prevented.

### Method of Manufacturing Sintered Body

To achieve the above objects, a method of manufacturing a sintered body according to the present disclosure includes: a carbonization step of thermally treating a molded body, which is obtained by molding a raw material composition, at a temperature of 500° C. to 1,000° C. to obtain a molded body, in which the raw material is partially carbonized; a first sintering step of thermally treating the molded body at a temperature of 2,100° C. to 2,300° C. after the carbonization step; and a second sintering step of thermally treating the molded body at a temperature of 2,200° C. to 2,320° C. after the first sintering step, wherein the raw material composition may include raw material granules obtained by spray drying a raw material slurry including boron carbide, a carbon-based material, a sinterability enhancer, and a solvent.

The boron carbide of the raw material composition may be in the form of powder. In this case, the boron carbide may be a powder having a high purity with a boron and carbon content of 98% by weight or more based on the entire weight of the powder.

The carbon-based material of the raw material composition may be a polymer resin, and may be in the form, in which the polymer resin is carbonized. For example, the carbon-based material may include a phenol-based resin, a polyvinyl alcohol-based resin, and the like.

The sinterability enhancer of the raw material composition may include boron oxide, a binder, and the like. In this case, the binder may include an acrylic resin.

The solvent of the raw material composition may include water, an alcohol-based material, and the like, and may be included at 60% by volume to 80% by volume, based on the total volume of the raw material slurry.

The raw material slurry may be provided through a stirring process such as ball milling, and the like. In this case, a ball mill stirring process may be performed for 5 hours to 20 hours using polymer balls, and the like.

The molded body in the carbonization step may be obtained by injecting a raw material into a mold, and applying pressure to the raw material, or may also obtained by subjecting the raw material to cold isostatic pressing (CIP), and the like. In this case, the pressure may be in a range of 100 MPa to 200 MPa.

The molded body in the carbonization step may be subjected to a process for removing an unnecessary part.

The heating to the thermal treatment temperature in the first sintering step may be performed for 10 hours to 15 hours.

The first sintering step may be performed for 0.5 hours to 2 hours.

The heating to the thermal treatment temperature in the second sintering step may be performed for 2 hours to 5 hours.

The second sintering step may be performed for 1 hour to 3 hours.

After the second sintering step, a cooling step of cooling the molded body to room temperature may be performed. In this case, the cooling step may be performed for 10 hours to 15 hours.

A sintered body having relatively coarse grains may be prepared through such a sintering step, and a good degree of densification may be achieved.

The sintered body obtained through the second sintering step may be further subjected to shape processing.

In the first sintering step, a predetermined heating rate may be applied until the thermal treatment temperature is reached, and the heating rate may be in a range of 1° C./min to 10° C./min, and in a range of 2° C./min to 5° C./min.

In the second sintering step, a predetermined heating rate may be applied until the thermal treatment temperature is reached, and the heating rate may be in a range of 0.1° C./min to 5° C./min, and may be in a range of 0.2° C./min to 1° C./min.

After the second sintering step, a predetermined temperature decrease rate may be applied in the cooling step, and the temperature decrease rate may be in a range of −10° C./min to −1° C./min, and in a range of −5° C./min to −2° C./min.

The first sintering step and the second sintering step may be performed at a pressure of 0.2 MPa or less, performed at a substantially normal pressure of (0.101 MPa), and performed at a pressure of 0.05 MPa or more.

Hereinafter, the present disclosure will be described in further detail with reference to the following Examples. However, it should be understood that the following Examples are provided to help the understanding of the present disclosure and the scope of the present disclosure is not limited thereto.

### Example 1: Manufacture of Sintered Body

14 parts by volume of boron carbide powder (commercially available from China Abrasive Industry Co., Ltd.) and 70 parts by volume of an ethanol solvent were mixed based on a total of 100 parts by volume of the mixture. Thereafter, a composition obtained by mixing 19.2 parts by weight of a phenol resin and 2 parts by weight of an acrylic binder based on 100 parts by weight of the mixture of the powder and the solvent was put into a blending machine, and mixed using a ball milling method to prepare a raw material slurry. This raw material slurry was spray dried through a nozzle to obtain raw material granules. Then, the raw material granules were charged into a mold to obtain a molded body. This molded body was thermally treated at a temperature of 800° C. to perform a carbonization step. Then, the molded body was heated to 2,200° C. at a heating rate of 3° C./min, and then thermally treated at 2,200° C. for an hour to perform a first sintering step. Then, the molded body was heated to 2,300° at 0.5° C./min, and then thermally treated at 2,300° C. for 2 hours to perform a second sintering step. Then, a cooling step of cooling the molded body to room temperature (25° C.) at 3° C./min was performed to manufacture a sintered body.

### Comparative Example 1: Silicon Carbide Prepared by Chemical Vapor Deposition

Silicon carbide (commercially available from KNJ Co., Ltd.) prepared by chemical vapor deposition (CVD) was prepared.

Experimental Example: Analysis of grain and composition of sintered body through electrolytic etching

The sintered body manufactured in Example 1 was electrochemically etched in 2% by volume of a KOH solution under the conditions of a flow rate of 12 to 20 sccm, 5 seconds and a voltage of 40 to 51 V, and then ultrasonically washed for 20 minutes. Before and after electrolytic etching, three random regions of the surface of the sintered body were photographed at a magnification of 500 to 1,000 using a scanning electron microscope (SEM). Thereafter, the volume ratio by grain size was analyzed, and the compositions in some positions (A, B, C, D, E, and F) were analyzed before and after electrolytic etching. The results are shown in FIGS. 1 and 3, and Tables 1, 2, and 3.

TABLE 1

| Grain size (μm) | Volume ratio (%) |
|---|---|
| 10 or less | 0.81 |
| Greater than 10 and 20 or less | 10.14 |
| Greater than 20 and 30 or less | 12.89 |
| Greater than 30 and 40 or less | 21.79 |
| Greater than 40 and 50 or less | 16.63 |
| Greater than 50 and 60 or less | 21.02 |
| Greater than 60 and 70 or less | 5.30 |
| Greater than 70 and 80 or less | 11.42 |

TABLE 2

| | Composition at | Composition at | Composition at |
|---|---|---|---|
| | position A | position B | position C |
| Elements | (% by weight) | (% by weight) | (% by weight) |
| B | — | — | 75.9 |
| C | 13.27 | 98.13 | 24.1 |
| O | — | 1.87 | — |
| Si | 85.23 | — | — |
| Al | 1.5 | — | — |

TABLE 3

| | Composition at | Composition at | Composition at |
|---|---|---|---|
| | position D | position E | position F |
| Elements | (% by weight) | (% by weight) | (% by weight) |
| B | — | — | 62.64 |
| C | 10.95 | 89.54 | 37.36 |
| O | 6.72 | 10.46 | — |
| Si | 81.24 | — | — |
| Al | 1.09 | — | — |

(a) of FIG. 1 shows the surface of the sintered body of Example 1 before electrolytic etching, (b) of FIG. 1 shows the surface of the sintered body of Example 1 after electrolytic etching, and (c) of FIG. 10 shows the identifiable grains on the surface of the sintered body of Example 1 after electrolytic etching by color.

(a) of FIG. 3 shows the surface of the sintered body of Example 1 and positions for composition measurement before electrolytic etching, and (b) of FIG. 3 shows the surface of the sintered body of Example 1 and positions for composition measurement after electrolytic etching.

Referring to Table 1 and (a) to (c) of FIG. 1, it can be seen that coarse grains having a size of several tens of micrometers were uniformly distributed and grains having a size of 10 μm or less were hardly present in the sintered body of Example 1.

Referring to Tables 2 and 3, and (a) to (c) of FIG. 3, it can be seen that the boron carbide, silicon carbide, glassy carbon, and the like were present on the surface of the sintered body of Example 1 before and after electrolytic etching.

Experimental Example: X-ray fluorescence spectrometry (XRF)

The compositions of the sintered body samples of Example 1 and Comparative Example 1 were subjected to X-ray fluorescence spectrometry (XRF) using a ZSX Primus apparatus (commercially available from Rigaku Corp.). The results are shown in Table 4.

TABLE 4

| | Example 1 | Comparative Example 1 |
|---|---|---|
| Elements | (% by weight) | (% by weight) |
| Carbon and boron | 99.258 | — |
| (pure) | | |
| B | 60.907 | — |
| C | 38.351 | 42.225 |
| O | 0.4459 | — |
| Na | 0.0136 | — |
| Mg | — | — |
| Al | 0.0088 | — |
| Si | 0.2164 | 57.775 |
| P | — | — |
| S | 0.0012 | — |
| Ca | 0.0083 | — |
| Ti | — | — |
| Cr | — | — |
| Mn | — | — |
| Fe | 0.0380 | — |
| Ni | 0.0050 | — |
| Ge | — | — |
| Y | 0.0048 | — |
| Ba | — | — |

Referring to Table 4, it can be seen that the sintered body of Example 1 included approximately 60.91% by weight of boron, 38.35% by weight of carbon, and traces of oxygen, silicon, and the like.

### Experimental Example: Measurement of Plasma Etching Rate

The plasma etching rates of the sintered body samples of Example 1 and Comparative Example 1 were measured under the following conditions. The results are shown in Tables 4 and 5, and FIGS. 4 and 5.

### Plasma Etching Conditions

Chamber pressure: 100 mTorr, plasma power: 800 W, exposure time: 300 minutes, CF₄ gas flow rate: 50 sccm, Ar gas flow rate: 100 sccm, O₂ gas flow rate: 20 sccm

(a) of FIG. 4 shows a surface state of the sintered body of Example 1 before plasma etching, and (b) of FIG. 4 shows a surface state of the sintered body of Example 1 after plasma etching.

(a) of FIG. 5 shows a surface state of the sintered body of Comparative Example 1 before plasma etching, and (b) of FIG. 5 shows a surface state of the sintered body of Comparative Example 1 after plasma etching.

TABLE 5

| | | Comparative |
|---|---|---|
| Items | Example 1 | Example 1 |
| Thickness (mm) before etching | 2.0036 | 1.9962 |
| Thickness (mm) after etching | 1.9726 | 1.9532 |
| Etching amount (mm) | 0.031 | 0.043 |
| Etching rate* | 1.55 | 2.15 |
| (%; thickness decrease rate (%)) | | |

*Etching rate: {(Thickness before etching − Thickness after etching)/(Thickness after etching)} × 100%

Referring to Table 5, it can be seen that Example 1 had superior plasma etching resistance compared to the silicon carbide prepared by CVD.

The sintered body according to the present disclosure can reduce the generation of impurity particles during plasma etching due to decreased line defects, can have excellent plasma etching resistance, and can help maintain plasma etching resistance.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A sintered body comprising boron carbide, wherein the sintered body comprises a zone, in which a volume ratio of grains having a grain size of greater than 30 μm and 60 μm or less is in a range of 50% to 70% based on a total volume of grains, as observed on a surface of the sintered body.

2. The sintered body of claim 1, wherein a volume ratio of the grains having a grain size of 10 μm or less is in a range of 0.01% to 1% based on the total volume of grains.

3. The sintered body of claim 1, wherein a volume ratio of the grains having a grain size of greater than 60 μm and 80 μm or less is in a range of 12% to 20% based on the total volume of grains.

4. The sintered body of claim 1, wherein the sintered body has an average grain size of 30 μm to 70 μm.

5. The sintered body of claim 1, wherein the sintered body has a boron and carbon content of 97% by weight or more based on a total weight of the sintered body.

6. The sintered body of claim 1, wherein the sintered body has an etching rate of 1.8% or less, as measured according to the following Equation 1 under plasma etching conditions, where a chamber pressure is 100 mTorr, a plasma power is 800 W, an exposure time is 300 minutes, a CF₄ gas flow rate is 50 sccm, an Ar gas flow rate is 100 sccm, and an O₂ gas flow rate is 20 sccm in the chamber:
Etching Rate={(Thickness before etching−Thickness after etching)/(Thickness after etching)}×100% [Equation 1]

7. The sintered body of claim 1, wherein the sintered body has a thermal conductivity at 25° C. of 23 W/mK or more and 42 W/mK or less.

8. A sintered body comprising boron carbide, wherein the sintered body has a carbon content of 30% by weight to 43% by weight based on the total weight of the sintered body, as measured by X-ray fluorescence spectrometry.

9. The sintered body of claim 8, wherein the sintered body has an oxygen content of 0.1% by weight to 0.9% by weight based on the total weight of the sintered body, as measured by X-ray fluorescence spectrometry.

10. The sintered body of claim 8, wherein the sintered body has a silicon content of 0.05% by weight to 0.5% by weight based on the total weight of the sintered body, as measured by X-ray fluorescence spectrometry.

11. The sintered body of claim 8, wherein the sintered body has a boron and carbon content of 97% by weight or more.

12. The sintered body of claim 8, wherein the sintered body has an etching rate of 1.8% or less, as measured according to the following Equation 1 under plasma etching conditions, where a chamber pressure is 100 mTorr, a plasma power is 800 W, an exposure time is 300 minutes, a CF₄ gas flow rate is 50 sccm, an Ar gas flow rate is 100 sccm, and an O₂ gas flow rate is 20 sccm in the chamber:
Etching Rate={(Thickness before etching−Thickness after etching)/(Thickness after etching)}×100% [Equation 1]

13. The sintered body of claim 8, wherein the sintered body has a thermal conductivity at 25° C. of 23 W/mK or more and 42 W/mK or less.

14. A method of manufacturing a sintered body comprising:
thermally treating a molded body, which is manufactured by molding a raw material composition, at a temperature of 500° C. to 1,000° C., to prepare a carbonized molded body;
thermally treating the carbonized molded body at a temperature of 2,100° C. to 2,300° C. to prepare a first sintered molded body; and
thermally treating the first sintered molded body at a temperature of 2,200° C. to 2,320° C. to prepare a second sintered molded body,
wherein the raw material composition comprises boron carbide, a carbon-based material, and a sinterability enhancer.

15. The method of claim 14, wherein the raw material composition comprises raw material granules obtained by spray drying a raw material slurry comprising boron carbide, a carbon-based material, a sinterability enhancer, and a solvent.

16. The method of claim 14, wherein the first sintered molded body and the second sintered molded body are prepared by sintering at a pressure of 0.2 MPa or less.

17. The method of claim 14, wherein the first sintered molded body is prepared by sintering for 0.5 hours to 2 hours.

18. The method of claim 14, wherein the second sintered molded body is prepared by sintering for 1 hour to 3 hours.

19. A part included in a plasma processing apparatus, wherein the part comprises the sintered body of claim 1.

20. A part included in a plasma processing apparatus, wherein the part comprises the sintered body of claim 8.
